(19) United States
(12) Patent Application Publication
(10) Pub. No.: US 2005/0057910 A1
(43) Pub. Date: Mar. 17, 2005

(54) Self contained wall mounted fold down workstation

(76) Inventor: Rodney Joseph Schnurr, Westminster, CO (US)

Correspondence Address: The Law Office of Craig W. Barber, PO Box 16220, Golden, CO, 80402-6004, US

(21) Appl. No.: 10/667,109

(22) Filed: Sep. 17, 2003

(51) Int. Cl. G06F 1/16; H05K 5/00; H05K 7/00; H05K 7/14; H05K 7/18

(52) U.S. Cl. 361/797

(57) ABSTRACT

The present invention teaches a self contained, wall mounted, fold down laptop computer work station. The station has six sides which form an enclosure. The interior width, height and depth dimensions of the enclosure are respectively substantially equal to width, depth and height dimensions of a laptop computer in the folded clamshell position, plus the width of a CD storage rack. A folding surface on the enclosure has the keyboard portion of such laptop computer secured thereto by hook and loop fabric fastening; when the folding surface is in the open position, the enclosure is open and such laptop computer may be opened, when the folding surface is in the closed position the enclosure is sealed shut. Moving the folding surface from the open position to the closed position causes such laptop computer to move to such folded clamshell position.

### FIELD OF THE INVENTION

This invention relates generally to workstations for laptop computers and specifically to a wall mounted workstation which folds.

### CROSS-REFERENCE TO RELATED APPLICATIONS

None.

### STATEMENT REGARDING FEDERALLY FUNDED RESEARCH

This invention was not made under contract with an agency of the US Government, nor by any agency of the US Government.

### BACKGROUND OF THE INVENTION

It is known that laptop computers sometimes come to be used in one location with a good deal of frequency. At such times, it would be useful to have a laptop workstation which could be easily mounted to a wall, which is of compact size, which automatically folds the laptop to the folded clamshell configuration when the laptop computer is not being used, which may secure the laptop from removal, which may itself fold to a minimal size, which includes storage space for computer paraphernalia and CD crystal cases, and which may organize computer cables and headphone cables.

### SUMMARY OF THE INVENTION

General Summary

The present invention teaches a self contained, wall mounted, fold down laptop computer work station. The station has six sides which form an enclosure. The interior width, height and depth dimensions of the enclosure are substantially equal to, respectively, the width, depth and height dimensions of a laptop computer in the folded clamshell position, plus the width of a CD storage rack in the width dimension. Thus the interior depth of the station is substantially equal to the folded height dimension of a laptop, while the interior height is substantially equal to the folded depth of the laptop from front to back. The interior width is substantially equal to the width of a folded laptop, plus the width of the CD storage rack. These dimensions are a result of the fact that laptop folds upwards as the station is closed, so that the laptop is internal and standing on what is normally its back edge. A folding surface on the enclosure has the keyboard portion of such laptop computer secured thereto by hook and loop fabric fastening; when the folding surface is in the open position, the enclosure is open and such laptop computer may be opened, when the folding surface is in the closed position the enclosure is sealed shut. Moving the folding surface from the open position to the closed position causes such laptop computer to move to such folded clamshell position, due to the fact that the display part of the laptop presses against the back of the station and is held stationary while the folding surface and the keyboard portion of the laptop continue to rotate.

The self contained work station includes hooks having an eye diameter dimensioned and configured to accept laptop computer cables and headphone cables. It further includes a latch/fastener to keep the folding surface closed, and a lock to prevent such latch/fastener from being opened. A grommet hole of size sufficient to accept four computer cables is located in the middle of the bottom plate. A top surface may be used to hold additional computer paraphernalia, and in addition may be used to hold books, as the side plates of the enclosure project upward past the top plate to from end pieces of the top surface.

Two mounting holes through the back plate accept screw or nail heads, and the CD storage rack has nine bays dimensioned and configured to accept one standard CD crystal case apiece.

The folding surface is secured to the bottom plate by means of three hinges, and is further secured at its ends to the side plates by means of folding struts.

Summary in Reference to Claims

It is therefore among the objects, advantages, aspects and embodiments of the present invention to provide a laptop computer workstation for use with a laptop computer of clamshell construction, such laptop computer furthermore being of clamshell construction having a keyboard portion and a display portion, the two portions hinged together at the back of the laptop computer device so that they may close into a folded clamshell position with the display portion atop the keyboard portion and having an open position in which the display portion projects above the laptop computer, such laptop computer having a folded height, a folded width, and a folded depth, such laptop computer further having a plurality of computer cables extending therefrom, the computer cables having a cable diameter, such laptop computer further having at least one headphone cable extending therefrom, the headphone cable having a headphone cable diameter, such laptop computer further having a bottom surface, the laptop computer workstation comprising: a back plate, first and second side plates, a top plate having an upper surface, and a bottom plate, the five plates secured together to form five sides of an enclosure, the enclosure having an internal height, an internal width, and an internal depth; a first portion of the first side plate and a second portion of the second side plate projecting above the top plate to form first and second end pieces of the upper surface of the top plate, a third portion of the backplate projecting above the top plate to form a back piece of the upper surface of the top plate, thereby forming a storage shelf having first and second end pieces and a back piece; a folding surface secured at a bottom edge to the bottom plate by a plurality of hinges, the folding surface secured at a first end to the first side plate and at a second end to the second side plate by folding struts; the folding surface having a first substantially horizontal open position in which it projects horizontally from the bottom plate and a second substantially vertical closed position in which it forms a sixth side of the enclosure; the folding surface and five plates dimensioned and configured so that when the folding surface is in the second closed position the enclosure is substantially sealed; a mouse holder affixed within the enclosure, the mouse holder dimensioned and configured to hold a standard mouse; a hook and loop fabric hold down device dimensioned and configured to secure such laptop computer keyboard portion to the folding surface when the folding surface is in the open and closed positions, the hold down device comprising a hooked fabric patch having a patch width substantially equal to such laptop computer folded width and having a patch depth substantially equal to such laptop computer folded depth, the hold down device further comprising a loop fabric patch on such bottom surface of such laptop computer, the loop fabric patch having the same width and depth as the hooked fabric patch; a first grommet hole located in the middle of the bottom plate, the grommet hole having a grommet diameter sufficient to accommodate four such computer cables therethrough; first and second mounting apertures passing through the back plate, each of the first and second mounting apertures being dimensioned and configured to accept the head of a standard wall mounting device; wherein the internal height of the enclosure is substantially such folded depth of such folded laptop computer; and further wherein the internal width of the enclosure is substantially such folded width of such folded laptop computer plus the CD storage rack width; and further wherein the internal depth of the enclosure is substantially such folded height of such folded laptop computer; whereby when the folding surface is moved from the open position to the closed position, such laptop computer display portion is urged against the backplate and held motionless while such laptop computer keyboard portion is rotated vertically, thereby moving such laptop computer substantially to such folded clamshell position.

It is therefore also among the objects, advantages, aspects and embodiments of the present invention to provide a workstation further comprising: first and second computer cable hooks secured to the back plate, the first and second computer cable hooks dimensioned and configured to each accept at least two such computer cables.

It is therefore also among the objects, advantages, aspects and embodiments of the present invention to provide a workstation further comprising: a first headphone cable hook secured to the back plate, the first headphone cable hook being dimensioned and configured to accept such first headphone cable.

It is therefore also among the objects, advantages, aspects and embodiments of the present invention to provide a workstation further comprising: a fastening device cooperating with the folding surface and the top plate, the fastening device having a first fastened position in which the folding surface is fastened in the second closed position and having a second unfastened position in which the folding surface is free to move between the open and closed positions.

It is therefore also among the objects, advantages, aspects and embodiments of the present invention to provide a workstation further comprising: a lock having a first locked position in which the fastening device is locked in the fastened position, whereby the enclosure is secured in the closed position, and having a second unlocked position in which the fastening device is free to move between the fastened and unfastened positions, whereby the folding surface is free to move between the open and closed positions.

It is therefore also among the objects, advantages, aspects and embodiments of the present invention to provide a workstation, wherein the plurality of hinges which secure the folding surface at the bottom edge to the bottom plate comprise three hinges.

It is therefore also among the objects, advantages, aspects and embodiments of the present invention to provide a workstation wherein the five plates are constructed from one member selected from the set consisting of: wood, metal, polymers, composite materials, and combinations thereof.

It is therefore also among the objects, advantages, aspects and embodiments of the present invention to provide a workstation further comprising: a first CD storage rack secured to such back plate within such enclosure, the CD storage rack having a plurality of bays, each bay being dimensioned and configured to accept one standard CD crystal case, the CD storage rack having a CD storage rack width.

It is therefore also among the objects, advantages, aspects and embodiments of the present invention to provide a workstation wherein the plurality of bays of the CD storage rack further comprise: at least nine bays.

It is therefore also among the objects, advantages, aspects and embodiments of the present invention to provide a workstation wherein the internal height further comprises 16 inches.

It is therefore also among the objects, advantages, aspects and embodiments of the present invention to provide a workstation wherein the internal width further comprises 23 inches.

It is therefore also among the objects, advantages, aspects and embodiments of the present invention to provide a workstation wherein the internal depth further comprises 6 inches.

### BRIEF DESCRIPTION OF THE DRAWINGS

FIG. 1 is a perspective view in the open position of a first embodiment of the invention.

FIG. 2 is a frontal view in the open position of a second, presently preferred embodiment of the invention.

FIG. 2a is a frontal view in the closed position.

FIG. 3 is a side view in the closed position of the second embodiment of the invention.

FIG. 3a is a side view in the closed position from the opposing side.

FIG. 4 is a back view of the second embodiment of the invention.

FIG. 5 is a top view.

FIG. 6 is a bottom view in the closed position of the second embodiment of the invention.

### LIST OF REFERENCE NUMERALS

100 First embodiment
102 Back plate
102a Back piece
104 First side plate
104a First end piece
106 Second side plate
106a Second end piece
108 Bottom plate
110 Folding surface
112 First folding strut
114 Second folding strut
116 Enclosure
118 Grommet hole
120 Top plate
122 Upper surface
200 Second embodiment
202 Back plate
202a Back piece
204 First side plate
204a First end piece
206 Second side plate
206a Second end piece
208 Bottom plate
210 Folding surface
212 First folding strut
214 Second folding strut
216 Enclosure
218 Grommet hole
220 Top plate
222 Upper surface
230 CD storage rack
232 Individual CD crystal case storage bay
234 First mounting aperture
236 Second mounting aperture
238 First fastening device
240 First hinge
242 Second hinge
244 Third hinge
246 Hold down device
250 First headphone cable hook
252 First computer cable hook
253 Mouse holder
254 Second computer cable hook
260 Lock

### DETAILED DESCRIPTION

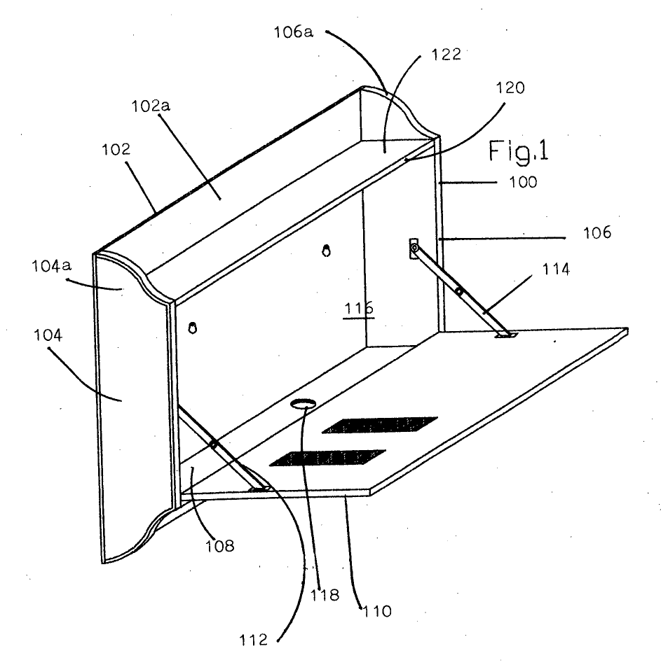

FIG. 1 is a perspective view in the open position of a first embodiment 100 of the invention. Back plate 102, first side plate 104, second side plate 106, bottom plate 108 and top plate 120 cooperate to form enclosure 116: these five plates are fastened together at their edges to form a shallow box shape, five sides of the enclosure. Folding surface 110 (attached to first side plate 104 by folding strut 112 and to second side plate 106 by folding strut 114 at opposite ends of folding surface 110) seals/shuts enclosure 116 when in an upright, substantially vertical and closed position (not shown in FIG. 1), that is it forms a sixth side of the enclosure, sealing it to prevent unauthorized access or removal of such laptop computer. When open in a substantially horizontal position, folding surface 110 projects from bottom plate 108 and forms a work surface on which such laptop computer (not shown) may be placed. Grommet hole 118 is located in the center of bottom plate 108 and is sized to accept a plurality of computer cables. Most computer cables have a diameter of approximately ¼ inch, thus grommet hole 118 may advantageously have a diameter of 1.5 inch so as to accommodate four such cables passing therethrough simultaneously without binding to each other, kinking, etc. It will be appreciated that cable management, in particular allowance of a graceful and esthetically pleasing exit of such cables from the immediate vicinity of the back of the computer from which the originate is becoming increasingly important.

Portions of first and second side plates 104, 106 project above upper surface 122 of top plate 120 to form end pieces 104a, 106a, while a portion of back plate 102 projects above upper surface 122 to form back piece 102a. The provision of adequate space for storage of books, disks, accessories, etc, is difficult: the provision of back piece 102a and end pieces 104a, 106a helps to solve this nagging problem.

Advantageously, folding surface 110 may have a depth (front to back) of 1 foot, 3 inches, and a width from end to end of 23 inches. The separation of top and bottom plates 108,120 may be 1 foot, 4 inches, and the depth (front to back) of side plates 104, 106 may be 6 inches. The height of back plate 102 may be 2 feet. The thickness of the component plates may be ¼ inch.

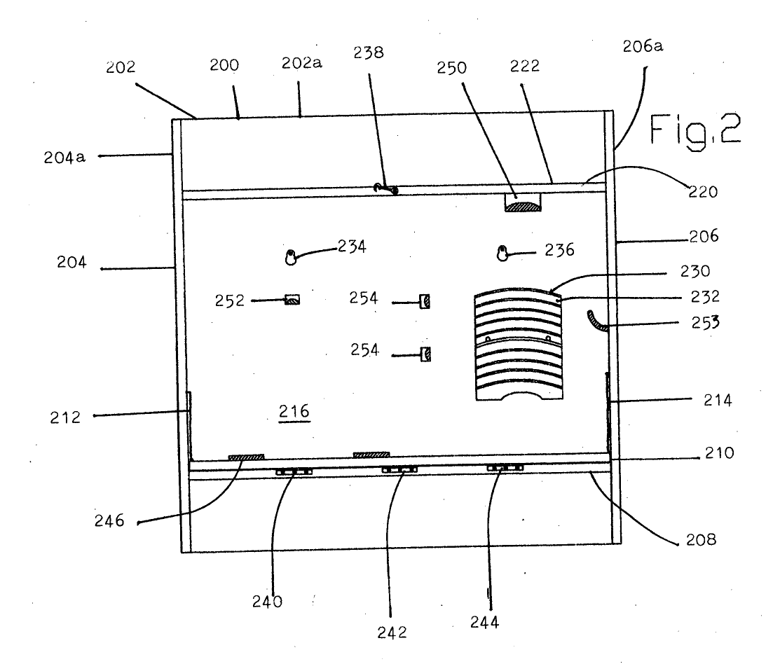

More importantly, the dimensions of the device may be selected in the following manner: the width of the internal enclosure 116 may be substantially the folded width of such folded laptop computer plus a CD storage rack width (see the second embodiment of FIG. 2, FIG. 2a), while the internal depth (front to back) of internal enclosure 116 may be substantially the folded height (top to bottom) of such laptop computer, and the internal height of the enclosure 116 may be substantially the folded depth (front to back) of such laptop computer in folded clamshell position. The dimensions of the enclosure 116 may be larger than these dimensions in alternative embodiments. The result is that when the folding surface is moved from the open position to the closed position, such laptop computer display is urged against the backplate and held motionless while such laptop computer is rotated vertically, thereby moving such laptop computer to the folded clamshell position.

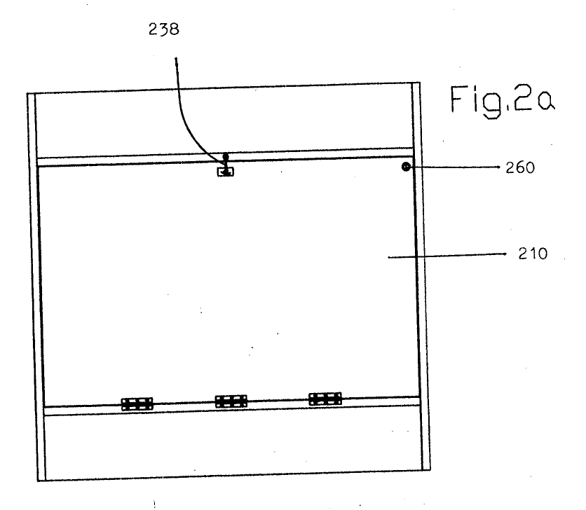

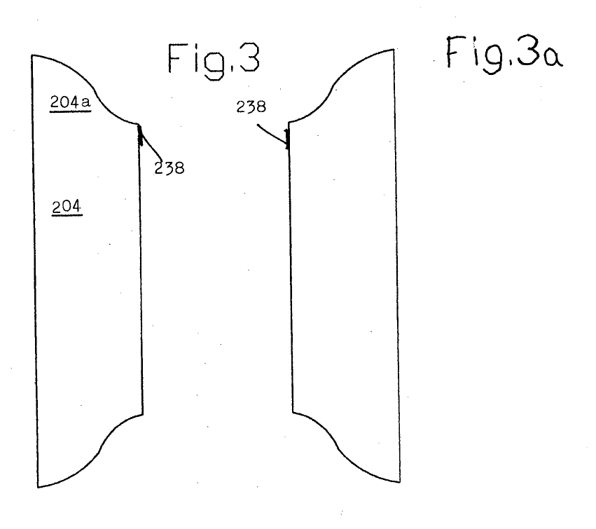

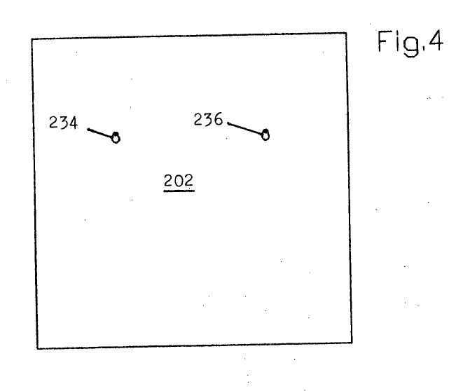

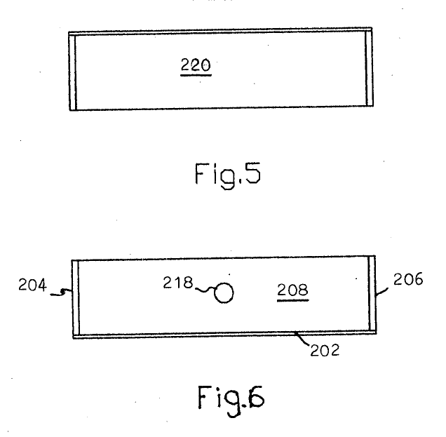

FIG. 2 is a frontal view in the open position of a second, presently preferred embodiment 200 of the invention, FIG. 2a is a frontal view in the closed position, FIG. 3 and FIG. 3a are side views of left and right sides in the closed position of the second embodiment 200 and FIG. 4 is a back view of the second embodiment 200, FIG. 6 is a bottom view in the closed position while FIG. 5 is a top view in the closed position. Additional details and features may be seen in this embodiment.

CD storage rack 230 is secured to back plate 202 or second side plate 206, inside of interior enclosure 216, and has nine bays such as bay 232 each of which is dimensioned and configured to store standard CD crystal cases. The width of CD storage rack 230 is added to the width of such computer in the folded clamshell position in computing the preferred width of the present invention, in the presently preferred embodiment and best mode presently contemplated for carrying out the invention. Adequate space for storage of Compact Digital disks (CDs) is becoming a premium item in computer workstations, especially as relates to laptop computers. For this reason, the prototype of the invention has been constructed with at least nine storage bays, a number found to be a useful minimum of storage capacity.

First and second mounting apertures 234, 236 passing through back plate 202 may also be seen, each of which is dimensioned and configured to accept the head of a standard wall mounting device such as a nail, screw, bolt, hook, etc.

First headphone cable hook 250 may be seen: this hook is dimensioned and configured to retain a headphone cable, in particular, the eye of the hook is of a diameter substantially equal or greater than the diameter of a standard headphone cable.

First and second computer cable hooks 252, 254 may be seen: these hooks are dimensioned and configured to retain a computer cable, in particular, the eyes of the hooks are of a diameter substantially equal or greater than the diameter of a standard computer cable. In the preferred embodiment, these eyes are dimensioned and configured to accept two such cables each.

Mouse holder 253 is dimensioned and configured to hold a standard mouse and is affixed within the enclosure. When folding surface 210 is closed, a mouse left unsecured will slide around, mouse holder 253 obviates this problem. Mouse holder 253 may be a hook, a bracket, a shelf, etc.

Fastening device 238, in the best mode now contemplated a hook, may be seen attached to top plate 220. This has a first fastened position in which the fastening device 238 cooperates with the folding surface 210 and the top plate 220. The fastening device 238 has a first fastened position in which the folding surface 210 is fastened in the closed position and also has a second unfastened position in which the folding surface 210 is free to move between the open and closed positions.

Lock 260 located in either top plate 220 or folding surface 210 (top plate 220 in this embodiment) cooperates with fastening device 238. Lock 260 has a first locked position in which fastening device 238 is locked in the fastened position, whereby enclosure 216 is secured in the closed position, and having a second unlocked position in which fastening device 238 is free to move between the fastened and unfastened positions, whereby folding surface 210 is free to move between the open and closed positions.

Hold down device 246 is dimensioned and configured to secure such laptop computer keyboard portion (not shown) to folding surface 210 when folding surface 210 is in the open and closed positions. Hold down device 246 comprises a hooked fabric patch having a patch width substantially equal to such laptop computer folded width and having a patch depth substantially equal to such laptop computer folded depth, and hold down device 246 also comprises a loop fabric patch (not shown) on such bottom surface of such laptop computer, the loop fabric patch having the same width and depth as the hooked fabric patch. The two patches may cooperate to hold such laptop computer secured to folding surface 210. An example of such hook and loop fabric is marketed under the trade name VELCRO (owner of registration not associated with present applicant). The five plates may be constructed from one member selected from the set consisting of: wood, metal, polymers, composite materials, and combinations thereof. In the prototype, wood has been utilized for commercial reasons, but high strength polymers may be used, or metal, composites of carbon, natural materials, polymers, ceramics, metals, etc may be used as appropriate.

The disclosure is provided to allow practice of the invention by those skilled in the art without undue experimentation, including the best mode presently contemplated and the presently preferred embodiment. Nothing in this disclosure is to be taken to limit the scope of the invention, which is susceptible to numerous alterations, equivalents and substitutions without departing from the scope and spirit of the invention. The scope of the invention is to be understood from the appended claims.

1. A laptop computer workstation for use with a laptop computer of clamshell construction, such laptop computer furthermore being of clamshell construction having a keyboard portion and a display portion, the two portions hinged together at the back of the laptop computer device so that they may close into a folded clamshell position with the display portion atop the keyboard portion and having an open position in which the display portion projects above the laptop computer, such laptop computer having a folded height, a folded width, and a folded depth, such laptop computer further having a plurality of computer cables extending therefrom, the computer cables having a cable diameter, such laptop computer further having at least one headphone cable extending therefrom, the headphone cable having a headphone cable diameter, such laptop computer further having a bottom surface, the laptop computer workstation comprising:
a back plate, first and second side plates, a top plate having an upper surface, and a bottom plate, the five plates secured together to form five sides of an enclosure, the enclosure having an internal height, an internal width, and an internal depth;
a first portion of the first side plate and a second portion of the second side plate projecting above the top plate to form first and second end pieces of the upper surface of the top plate, a third portion of the backplate projecting above the top plate to form a back piece of the upper surface of the top plate, thereby forming a storage shelf having first and second end pieces and a back piece;
a folding surface secured at a bottom edge to the bottom plate by a plurality of hinges, the folding surface secured at a first end to the first side plate and at a second end to the second side plate by folding struts;
the folding surface having a first substantially horizontal open position in which it projects horizontally from the bottom plate and a second substantially vertical closed position in which it forms a sixth side of the enclosure;
the folding surface and five plates dimensioned and configured so that when the folding surface is in the second closed position the enclosure is substantially sealed;
a hook and loop fabric hold down device dimensioned and configured to secure such laptop computer keyboard portion to the folding surface when the folding surface is in the open and closed positions, the hold down device comprising a hooked fabric patch having a patch width substantially equal to such laptop computer folded width and having a patch depth substantially equal to such laptop computer folded depth, the hold down device further comprising a loop fabric patch on such bottom surface of such laptop computer, the loop fabric patch having the same width and depth as the hooked fabric patch;
a first grommet hole located in the middle of the bottom plate, the grommet hole having a grommet diameter sufficient to accommodate four such computer cables therethrough;
a mouse holder affixed within the enclosure, the mouse holder dimensioned and configured to hold a standard mouse;
first and second mounting apertures passing through the back plate, each of the first and second mounting apertures being dimensioned and configured to accept the head of a standard wall mounting device;
wherein the internal height of the enclosure is substantially such folded depth of such folded laptop computer; and further
wherein the internal width of the enclosure is substantially such folded width of such folded laptop computer; and further
wherein the internal depth of the enclosure is substantially such folded height of such folded laptop computer;
whereby when the folding surface is moved from the open position to the closed position, such laptop computer display portion is urged against the backplate and held motionless while such laptop computer keyboard portion is rotated vertically, thereby moving such laptop computer substantially to such folded clamshell position.

2. The workstation of claim 1, further comprising: first and second computer cable hooks secured to the back plate, the first and second computer cable hooks dimensioned and configured to each accept at least two such computer cables.

3. The workstation of claim 1, further comprising: a first headphone cable hook secured to the back plate, the first headphone cable hook being dimensioned and configured to accept such first headphone cable.

4. The workstation of claim 1, further comprising: a fastening device cooperating with the folding surface and the top plate, the fastening device having a first fastened position in which the folding surface is fastened in the second closed position and having a second unfastened position in which the folding surface is free to move between the open and closed positions.

5. The workstation of claim 4, further comprising: a lock having a first locked position in which the fastening device is locked in the fastened position, whereby the enclosure is secured in the closed position, and having a second unlocked position in which the fastening device is free to move between the fastened and unfastened positions, whereby the folding surface is free to move between the open and closed positions.

6. The workstation of claim 1, wherein the plurality of hinges which secure the folding surface at the bottom edge to the bottom plate comprise three hinges.

7. The workstation of claim 1, wherein the five plates are constructed from one member selected from the set consisting of: wood, metal, polymers, composite materials, and combinations thereof.

8. The workstation of claim 1, further comprising: a first CD storage rack secured to such back plate within such enclosure, the CD storage rack having a plurality of bays, each bay being dimensioned and configured to accept one standard CD crystal case, the CD storage rack having a CD storage rack width; wherein
the internal width of the enclosure is substantially such folded width of such folded laptop computer plus additionally the CD storage rack width.

9. The workstation of claim 8, wherein the plurality of bays of the CD storage rack further comprise: at least nine bays.

10. The workstation of claim 1, wherein the internal height further comprises 16 inches.

11. The workstation of claim 1, wherein the internal width further comprises 23 inches.

12. The workstation of claim 1, wherein the internal depth further comprises 6 inches.
